(19) United States
(12) Patent Application Publication
(10) Pub. No.: US 2026/0266480 A1
(43) Pub. Date: Sep. 10, 2026

(54) DEHUMIDIFIER

(71) Applicant: LG ELECTRONICS INC., Seoul (KR)

(72) Inventors: Sangjin Park, Seoul (KR); JinWoo Been, Seoul (KR); Hyunwoo Lee, Seoul (KR)

(73) Assignee: LG ELECTRONICS INC., Seoul (KR)

(21) Appl. No.: 19/236,656

(22) Filed: Jun. 12, 2025

(30) Foreign Application Priority Data
Mar. 10, 2025 (KR) 10-2025-0030464

(51) Int. Cl. F24F 1/0358; F24F 13/20

(52) U.S. Cl. CPC F24F 1/0358; F24F 13/20

(57) ABSTRACT

Proposed is a dehumidifier which allows indoor air drawn in by air suction force generated by the operation of a fan assembly to pass through an electric part and dissipate heat from the electric part. To this end, the dehumidifier incudes a heat dissipation guide part formed on one portion of a base frame, in which the heat dissipation guide part guides air from an indoor space to be drawn in and discharged to the electric part when the fan assembly is operated.

### CROSS REFERENCE TO RELATED APPLICATION

The present application claims priority to Korean Patent Application No. 10-2025-0030464, filed March 10, 2025, the entire contents of which are incorporated herein for all purposes by this reference.

### BACKGROUND OF THE INVENTION

### Field of the Invention

The present disclosure relates generally to a dehumidifier. More particularly, the present disclosure relates to a dehumidifier having a heat dissipation structure for dissipating heat from an electric part provided for controlling the operation of the dehumidifier.

### Description of the Related Art

Generally, a dehumidifier is a device or appliance that removes moisture from air in an indoor space.

Such a dehumidifier is configured to remove moisture from air in a space by drawing in the air and passing the air through a heat exchanger, thereby removing the moisture from the air through heat exchange with the heat exchanger.

The heat exchanger includes a condenser that condenses refrigerant and an evaporator that evaporates refrigerant. That is, while air passes through the evaporator, the air exchanges heat with refrigerant, thereby removing moisture of the air, and while the air passes through the condenser, the air absorbs the heat released from the refrigerant and is supplied indoors in a dried state, thereby lowering the humidity of the indoor space.

In addition, the dehumidifier has a water tank and is configured to collect and store moisture separated from air while the air passes through the evaporator, and then discharge the moisture when necessary.

Regarding the conventional dehumidifier, various patents are provided, such as Korean Patent No. 10-2506410, Korean Patent Application Publication No. 10-2025-0006644, Korean Patent Application Publication No. 10-2025-0006645, Korean Patent Application Publication No. 10-2025-0006646, and Korean Patent Application Publication No. 10-2025-0006647.

Meanwhile, a dehumidifier is provided with an electric part for controlling the operations of various devices, and the electric part generates a large amount of heat while the dehumidifier is operating. The heat generated from the electric part affects the performance of surrounding components and also affects various circuits that make up the electric part.

Therefore, heat dissipation for the electric part is essential.

In the related art, heat sinks were installed on various circuit components or circuit boards that make up an electric part, and a separate fan (box fan) was used to forcibly direct air to pass through the heat sinks so that heat is dissipated from the electric part.

However, in the case of a structure utilizing the box fan, since a space for installing the box fan and a structure for airflow are further required, the overall size of the electric part inevitably increases, and as a result, the overall size of the dehumidifier inevitably increases.

In addition, considering that a compressor is installed near a space in which the electric part is located, when the box fan was used, high-temperature heat generated from the compressor flowed to the electric part, so a cooling effect was not great.

### Documents of Related Art

((Patent Document 1) Korean Patent No.10-2506410

(Patent Document 2) Korean Patent Application Publication No. 10-2025-0006644

(Patent Document 3) Korean Patent Application Publication No. 10-2025-0006645

(Patent Document 4) Korean Patent Application Publication No. 10-2025-0006646

(Patent Document 5) Korean Patent Application Publication No. 10-2025-0006647

### SUMMARY OF THE INVENTION

Accordingly, the present disclosure has been made keeping in mind the above problems occurring in the related art, and the present disclosure is intended to provide a new type of dehumidifier that enables efficient heat dissipation for an electric part.

The present disclosure is intended to provide a new type of dehumidifier that enhances heat dissipation performance while minimizing the volume of an electric part.

The present disclosure is intended to provide a new type of dehumidifier that allows heat to be dissipated from an electric part by using natural convection, thereby eliminating need for a separate heat-dissipating fan.

The present disclosure is intended to provide a new type of dehumidifier that improves the performance of dissipating heat from an electric part by allowing air introduced into a space in which the electric part is located to sufficiently pass through the electric part before being discharged.

In order to achieve the objectives, according to the dehumidifier of the present disclosure, indoor air drawn in by air suction force generated by the operation of a fan assembly may dissipate heat from an electric part while the air passes through the electric part.

According to the dehumidifier of the present disclosure, a structure may be provided to discharge air, which is drawn in from outside a casing, toward the electric part to so as to dissipate heat from the electric part.

According to the dehumidifier of the present disclosure, the structure for dissipating heat from the electric part may include a heat dissipation guide part. Accordingly, air outside the casing may be supplied to the electric part through the heat dissipation guide part.

According to the dehumidifier of the present disclosure, the heat dissipation guide part for dissipating heat from the electric part may be formed on a base frame.

According to the dehumidifier of the present disclosure, the heat dissipation guide part may be formed on the base frame that air outside the casing is guided to be discharged to the electric part.

According to the dehumidifier of the present disclosure, the heat dissipation guide part may be formed as an opening of a predetermined size or as a tubular body having an opening of a predetermined size.

According to the dehumidifier of the present disclosure, a partition frame may be provided within the casing so as to divide an installation space provided within the casing into a plurality of spaces.

According to the dehumidifier of the present disclosure, the partition frame may be formed to divide the space within the casing into an upper space and a lower space.

According to the dehumidifier of the present disclosure, the partition frame may have a first vertical partition wall formed to separate a first space from a third space in the lower space within the casing.

According to the dehumidifier of the present disclosure, the partition frame may have a second vertical partition wall formed to separate a second space from the third space in the lower space within the casing.

According to the dehumidifier of the present disclosure, the first vertical partition wall and the second vertical partition wall may be formed on the partition frame to divide the lower space within the casing into the first space, the second space, and the third space.

According to the dehumidifier of the present disclosure, the first space may be formed as a space provided between the partition frame and a first side peripheral surface within the casing. The electric part may be located within the first space.

According to the dehumidifier of the present disclosure, the second space may be formed as a space provided between the partition frame and a second side peripheral surface within the casing. A water tank may be located within the second space.

According to the dehumidifier of the present disclosure, the third space may be provided between the first space and the second space. A compressor may be located within the third space.

According to the dehumidifier of the present disclosure, the electric part may be located in the first space, the water tank may be located in the second space, and the compressor may be located in the third space.

According to the dehumidifier of the present disclosure, the heat dissipation guide part may be formed to allow air to flow into the first space.

According to the dehumidifier of the present disclosure, the heat dissipation guide part may be formed as a tubular body that protrudes upward from the base frame and has an open interior. Accordingly, even if condensate accumulates on the upper surface of the base frame, leakage of the condensate onto the indoor floor through the heat dissipation guide part may be prevented.

According to the dehumidifier of the present disclosure, the heat dissipation guide part may be formed to be open toward a portion of the lower surface of the electric part. Accordingly, air outside the casing that is introduced through the heat dissipation guide part may be directly supplied to the electric part.

According to the dehumidifier of the present disclosure, the heat dissipation guide part may be formed to have an elongated opening. Accordingly, the heat dissipation guide part may discharge air outside the casing to as many portions as possible along a longitudinal direction of the lower surface of the electric part.

According to the dehumidifier of the present disclosure, a first opening may be formed on the lower surface of the electric part. Accordingly, a portion of air introduced into the casing through the heat dissipation guide part may be supplied into the electric part through the first opening.

According to the dehumidifier of the present disclosure, the first opening and the opening of the heat dissipation guide part may be positioned to be misaligned vertically. Accordingly, a portion of air introduced into the casing through the heat dissipation guide part may pass through the first opening and flow through the interior of the electric part.

According to the dehumidifier of the present disclosure, a second opening may be formed on the upper surface of the electric part. Accordingly, air passing through the electric part may flow through the second opening to an air inlet of the fan assembly.

According to the dehumidifier of the present disclosure, to dissipate heat from circuit components by using air flowing along the outer surface of the electric part, a heat dissipation fin connected to the circuit components may be installed to be exposed to the outer surface of the electric part.

According to the dehumidifier of the present disclosure, the heat dissipation fin may be formed by installing a plurality of thin plates spaced apart from each other, and each of the thin plates may be formed to have a different length along the inclination or curvature of the inner surface of the casing adjacent to the thin plate.

According to the dehumidifier of the present disclosure, the partition frame may include a passage hole through which air passes. Accordingly, air that has absorbed heat dissipated from the electric part may flow through the passage hole into the upper space within the casing.

According to the dehumidifier of the present disclosure, the passage hole may be positioned to be vertically misaligned with the second opening of the upper surface of the electric part. Accordingly, condensate falling into the passage hole may be prevented from flowing into the electric part through the second opening.

According to the dehumidifier of the present disclosure, the partition frame may include a guide to guide air passing through the electric part.

According to the dehumidifier of the present disclosure, the guide and the opening of the heat dissipation guide part may be positioned to be misaligned vertically. Accordingly, air passing through the heat dissipation guide part may flow to the guide after dissipating heat from the electric part while the air passes through the electric part.

According to the dehumidifier of the present disclosure, to guide air passing through the electric part to flow toward the guide, the partition frame may be formed to be inclined upward gradually toward a peripheral portion thereof.

According to the dehumidifier of the present disclosure, in order to guide air passing through the electric part to flow toward the guide, the partition frame may be formed to be inclined upward gradually toward a portion on which the guide is formed.

According to the dehumidifier of the present disclosure, the guide may be formed on one periphery of the partition frame so that the upper space and the lower space communicate with each other so as to allow air to pass through the guide.

According to the dehumidifier of the present disclosure, in order to prevent condensate present on the upper surface of the partition frame from falling downward through the guide, the upper end of the guide may be formed to protrude upward from the upper surface of the partition frame.

As described above, according to the dehumidifier of the present disclosure, the heat dissipation guide part may be formed on the base frame, thereby dissipating heat from the electric part even if a separate heat-dissipating fan is not provided for heat dissipation.

According to the dehumidifier of the present disclosure, a separate heat-dissipating fan may not be provided, thereby minimizing the volume of the electric part.

According to the dehumidifier of the present disclosure, the opening through which air is drawn into the first space in which the electric part is located and the opening through which air is discharged may be positioned as far apart from each other as possible, and the electric part may be positioned therebetween, thereby improving the performance of dissipating heat of the electric part.

According to the dehumidifier of the present disclosure, the heat dissipation fin of the electric part may be formed to be exposed to the outside of a cabinet, and air may be allowed to flow along the surface of the cabinet and pass through the heat dissipation fin, thereby improving the performance of dissipating heat of the circuit components.

According to the dehumidifier of the present disclosure, by additionally forming an opening for air inflow or outflow in the electric part, air suction force generated by the fan assembly may forcibly discharge heat from the inside of the electric part to the outside of the cabinet, and forcibly introduce air into the cabinet of the electric part, thereby dissipating heat from the circuit components.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a perspective view of a dehumidifier according to an embodiment of the present disclosure;

FIGS. 2 and 3 are exploded perspective views of the dehumidifier according to the embodiment of the present disclosure;

FIG. 4 is a plan view of the dehumidifier according to the embodiment of the present disclosure;

FIG. 5 is a cross-sectional view taken along line A-A of FIG. 4 with a water tank separated;

FIG. 6 is a cross-sectional view taken along line B-B of FIG. 4;

FIG. 7 is a perspective view illustrating the installation states of a partition frame, a base frame, and an electric part of the dehumidifier according to the embodiment of the present disclosure;

FIG. 8 is a perspective view illustrating a state in which the electric part is removed among the partition frame, the base frame, and the electric part of the dehumidifier according to the embodiment of the present disclosure;

FIG. 9 is an enlarged view of part “A” of FIG. 8;

FIG. 10 is a front view of the partition frame of the dehumidifier according to the embodiment of the present disclosure;

FIG. 11 is a perspective view illustrating a state in which the partition frame and the base frame are separated from each other in the dehumidifier according to the embodiment of the present disclosure;

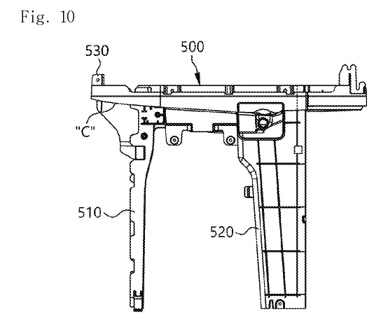

FIG. 12 is an enlarged view of part “B” of FIG. 11;

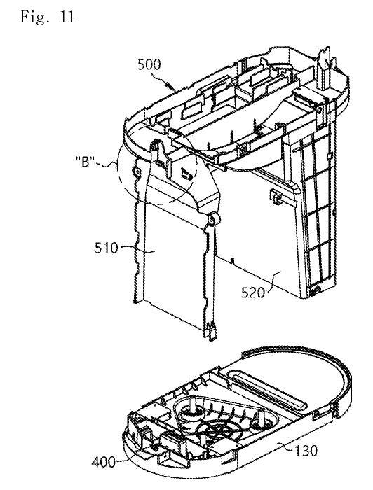

FIG. 13 a side view of the combined state of the partition frame and the base frame of the dehumidifier according to the embodiment of the present disclosure as viewed from a first vertical partition wall side;

FIG. 14 is a plan view of the combined state of the partition frame and the base frame of the dehumidifier according to the embodiment of the present disclosure;

FIG. 15 is a perspective view of a cabinet of the electric part of the dehumidifier according to the embodiment of the present disclosure, with a second cover separated;

FIG. 16 is a perspective view of the electric part of the dehumidifier according to the embodiment of the present disclosure as viewed from the lower side; and

FIG. 17 is a cross-sectional view in a plan view to illustrate another embodiment of a heat dissipation fin in the dehumidifier according to the embodiment of the present disclosure.

### DETAILED DESCRIPTION OF THE INVENTION

Embodiments of the present disclosure are described in detail with reference to exemplary drawings. When adding reference numerals to components in each drawing, it should be noted that identical components are given the same reference numerals as much as possible even if they are shown in different drawings.

In addition, when describing the embodiments of the present disclosure, if a detailed description of the relevant known configuration or function is judged to hinder understanding of the embodiments of the present disclosure, detailed descriptions thereof will be omitted.

In addition, in describing the components of the embodiments of the present disclosure, terms such as first, second, A, B, (a), and (b) may be used. These terms are only for distinguishing the components from other components, and the nature or order of the components is not limited by the terms. When a component is described as being "connected" or "coupled" to another component, the component may be directly connected to or coupled to the another component, but it should be understood that still another component may be "connected" or "coupled" thereto between each component.

Hereinafter, preferred embodiments of a dehumidifier of the present disclosure are described with reference to the attached drawings 1 to 17.

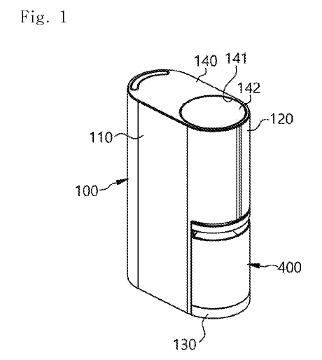

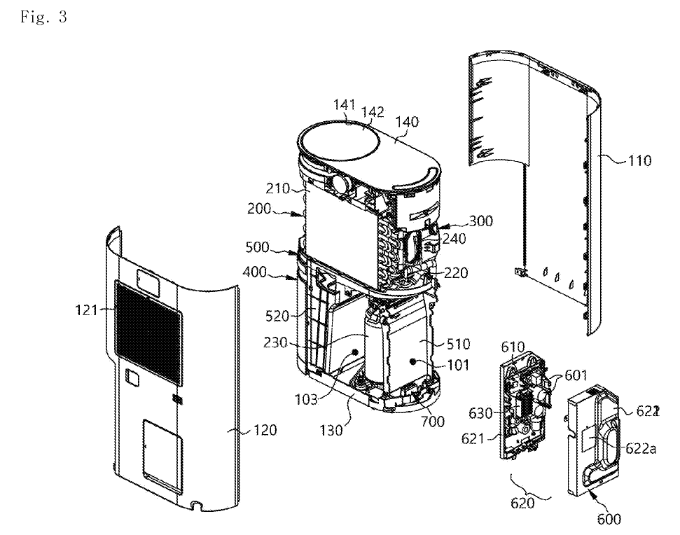

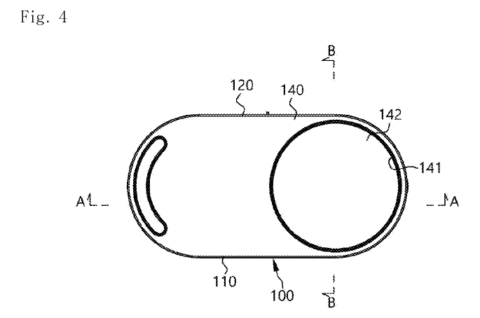

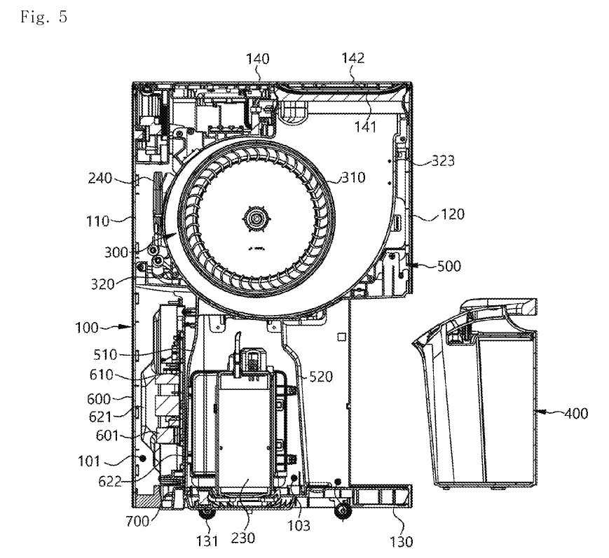

FIGS. 1 to 3 are perspective views and exploded perspective views of the dehumidifier according to an embodiment of the present disclosure. FIG. 4 is a plan view of the dehumidifier according to the embodiment of the present disclosure, and FIGS. 5 and 6 are a front cross-sectional view and a side cross-sectional view, respectively, taken from different directions.

As illustrated in these drawings, the dehumidifier according to the embodiment of the present disclosure may include a casing 100, a dehumidifying part 200, a fan assembly 300, and an electric part 600. In particular, the electric part 600 may be configured to allow heat to be dissipated by a heat dissipation guide part 700.

The dehumidifier of the embodiment of the present disclosure is described in more detail for each component as follows.

First, the dehumidifier according to the embodiment of the present disclosure may include the casing 100.

The casing 100 may be defined as a portion which constitutes a peripheral wall of the exterior of the dehumidifier.

The casing 100 may be formed to be open vertically while providing space for various components or devices to be installed inside.

The casing 100 may be formed by coupling a plurality of parts to each other. For example, the casing 100 may be divided into and provided as a first peripheral casing 110 and a second peripheral casing 120.

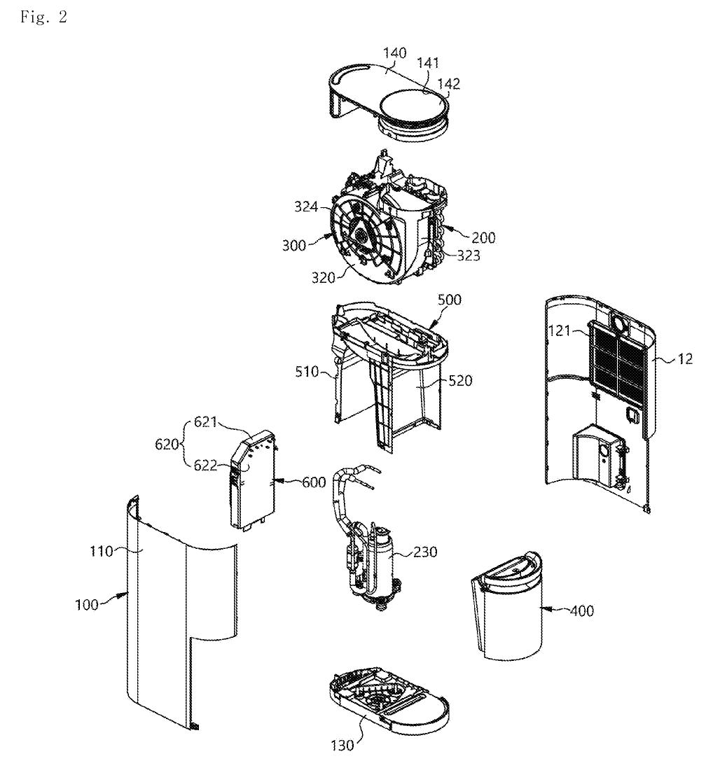

The first peripheral casing 110 may constitute the front surface of the dehumidifier part, a portion of a first side wall thereof, and a portion of a second side wall thereof, and the second peripheral casing 120 may constitute the rear surface of the dehumidifier, another portion of the first side wall, and another portion of the second side wall. For convenience of explanation, in the state of FIGS. 1 and FIG. 2, the surface of the dehumidifier at a side at which a water tank 400 is located may be defined as a right surface, and the surface of the dehumidifier at the opposite side of the water tank 400 may be defined as a left surface. Referring to FIG. 4, the surface of the dehumidifier on which the first peripheral casing 110 is positioned may be defined as a front surface, and the surface of the dehumidifier on which the second peripheral casing 120 is positioned may be defined as the rear surface. Although not shown, the casing 100 may additionally be provided with separate peripheral casings that constitutes side walls.

An intake port 121 may be formed in the second peripheral casing 120. For example, the intake port 121 for drawing in air outside the casing (e.g., indoor air) may be formed in the upper portion of the second peripheral casing 120.

The lower right portion of the casing 100 may be formed to be open. For example, the lower portion of the right wall of the first peripheral casing 110 and the lower portion of the left wall of the second peripheral casing 120 may be formed to be open. The water tank 400 may be detachably installed within the open portions. The water tank 400 may store moisture separated from air.

Next, the dehumidifier according to the embodiment of the present disclosure may include a base frame 130.

The base frame 130 may be defined as a portion constituting the bottom of the exterior of the dehumidifier.

The base frame 130 is formed to block the open lower surface of the casing 100.

As shown in FIGS. 5 and 6, a plurality of rolling members 131 for moving the dehumidifier may be provided on the lower surface of the base frame 130.

Each of the rolling members 131 may be provided as a caster.

Next, the dehumidifier according to the embodiment of the present disclosure may include an upper cover 140.

The upper cover 140 may be defined as a part constituting the upper surface of the exterior of the dehumidifier.

The upper cover 140 may be formed to block the open upper surface of the casing 100.

A discharge port 141 may be formed on the upper cover 140. The discharge port 141 may be formed on one side portion of the upper cover 140. For example, in a plan view, the discharge port 141 may be formed on the right side portion of the upper cover 140.

The discharge port 141 may be selectively opened and closed by an opening/closing door 142. The opening/closing door 142 may be opened and closed manually or automatically.

Although not shown, the first peripheral casing 110 and the second peripheral casing 120 may be formed integrally with each other, or one of the peripheral casings 110 and 120 and the base frame 130 or one of the peripheral casings 110 and 120 and the upper cover 140 may be formed integrally with each other.

Next, the dehumidifier according to the embodiment of the present disclosure may include a partition frame 500.

The partition frame 500 may be defined as an inner body of the dehumidifier. That is, a space within the casing 100 may be divided into a plurality of spaces by the partition frame 500.

The partition frame 500 may divide the space within the casing 100 into upper and lower parts. For this purpose, the partition frame 500 may be formed to be located between an upper space and a lower space within the casing 100. Accordingly, the space within the casing 100 may be divided into the upper space and the lower space by the partition frame 500.

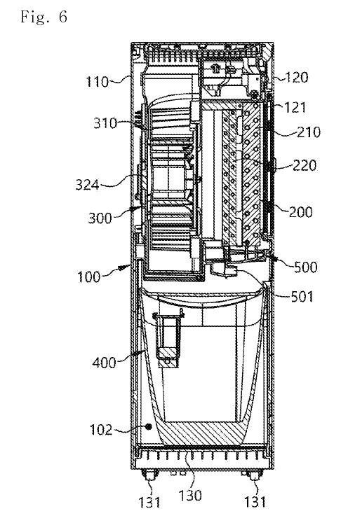

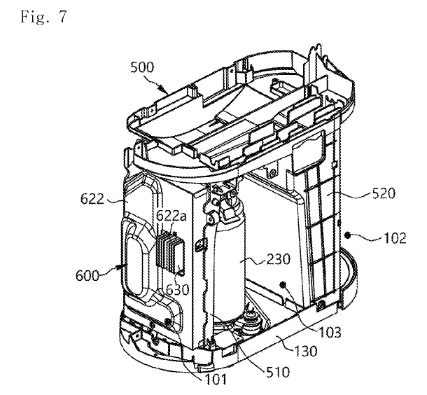

FIGS. 7 to 10 illustrate a relationship between the partition frame 500 and the base frame 130.

As shown in these drawings, the partition frame 500 may include a first vertical partition wall 510 and a second vertical partition wall 520 so as to divide the lower space within the casing 100 into a first space 101, a second space 102, and a third space 103.

The first vertical partition wall 510 may be formed to protrude downward from a first side of the lower surface of the partition frame 500 so as to separate the first space 101 from the third space 103 in the lower space within the casing 100.

The second vertical partition wall 520 may be formed to protrude downward from a second side of the lower surface of the partition frame 500 so as to separate the second space 102 from the third space 103 in the lower space within the casing 100.

Referring to FIG. 5, the first space 101 may be defined as a space provided between the partition frame 500 and a first side peripheral surface (for example, a left peripheral surface) within the casing 100, and the electric part 600 may be positioned within the first space 101.

The second space 102 may be defined as a space provided between the partition frame 500 and a second side peripheral surface (e.g., a right peripheral surface) within the casing 100, and the water tank 400 may be positioned within the second space 102.

The third space 103 may be defined as a space provided between the first space 101 and the second space 102, and a compressor 230 may be positioned within the third space 103.

The dehumidifying part 200 and the fan assembly 300, which will be described later, may be installed on the upper surface of the partition frame 500. Considering this, the partition frame 500 may also function as a condensate tray to receive condensate falling from the dehumidifying part 200.

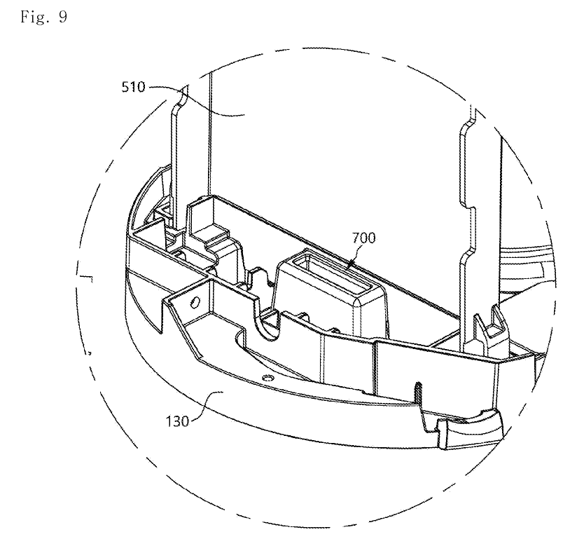

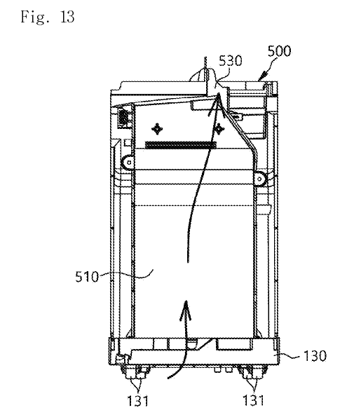

A drain hole 501 (see FIG. 14) may be formed on the upper surface of the partition frame 500 to allow the condensate to fall into the water tank 400 within the second space 102. In addition, the upper surface of the partition frame 500 may be formed to be inclined toward the drain hole 501 (see FIG. 10). Accordingly, condensate that flows down onto the upper surface of the partition frame 500 may be guided to the drain hole 501 and then fall into the water tank through the drain hole 501.

The lower surface of the partition frame 500 may be formed to be inclined upward gradually toward a peripheral portion thereof. Specifically, the portion (a "C" portion in the drawing) of the lower surface of the partition frame 500 that forms the upper surface of the first space 101 may be formed to be inclined upward gradually toward the peripheral portion. Preferably, the lower surface of the partition frame 500 may be formed to be inclined upward gradually toward the peripheral portion, with reference to the drain hole 501. Accordingly, air flowing upward from the first space 101 may flow toward the peripheral portion along the slope of the lower surface of the partition frame 500.

Meanwhile, the guide 530 through which air rising from the first space 101 passes and is guided to the upper space of the partition frame 500 (the upper space within the casing) may be formed on one portion of the periphery of the partition frame 500 located in the first space 101. That is, the guide 530 may be formed to guide airflow from the uppermost portion of the lower surface of the partition frame 500. Preferably, the partition frame 500 may be formed to be inclined upward gradually toward the portion in which the guide 530 is formed. With this structure, air rising from the first space 101 may flow along the lower surface of the partition frame 500, flow toward the guide 530, and then be guided by the guide 530 to flow into the upper space within the casing 100.

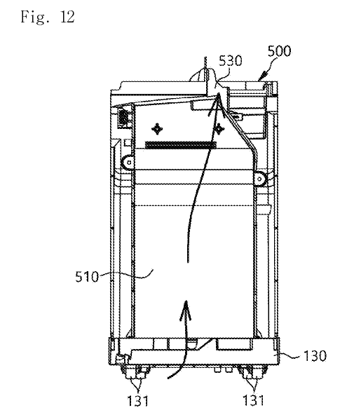

As illustrated in FIG. 13, the guide 530 may be formed at a corner portion of the upper surface of the first space 101. Accordingly, air rising from the lower portion within the first space 101 may flow along the inclined lower surface of the partition frame 500, flow to the guide 530, and then flow to the upper space within the casing 100.

Although not shown, the guide 530 may be formed as an opening. However, when the guide 530 is formed as a simple opening, condensate that falls onto the upper surface of the partition frame 500 may flow down through the opening. Considering this, the guide 530 may be formed so that an upper end of the guide 530 protrudes further from the upper surface of the partition frame 500 to prevent condensate present on the upper surface of the partition frame 500 from falling downward through the guide 530.

Next, the dehumidifier according to the embodiment of the present disclosure may include the dehumidifying part 200.

The dehumidifying part 200 may be defined as a device, apparatus or structure for separating moisture from air.

For example, the dehumidifying part 200 may be configured to separate moisture contained in the air by heat exchange with the air by using a temperature difference. For this purpose, the dehumidifying part 200 may include a heat exchanger 210 and 220.

The heat exchangers 210 and 220 may be located in the rear space (the space adjacent to the second peripheral casing) of the upper space within the casing 100.

The heat exchanger 210 and 220 may include an evaporator 210 for separating moisture from air by utilizing a temperature difference from the air.

Air passing through the evaporator 210 may have a low temperature because the air exchanges heat with the low-temperature refrigerant of the evaporator 210. When such low-temperature air is directly provided indoors, it may cause complaint of a user. Taking this into account, the heat exchanger 210 and 220 may include a condenser 220 to increase the temperature of the air.

The condenser 220 may be located on the air outlet side of the evaporator 210. In particular, the evaporator 210 and the condenser 220 may be positioned to overlap in an air flow direction and be provided in a portion in which the intake port 121 of the second peripheral casing 120 is formed inside the casing 100. For example, the evaporator 210 and the condenser 220 may be provided in the right space of an upper portion within the casing 100. The evaporator 210 may be arranged closer to the intake port 121 than the condenser 220. With such an arrangement of the evaporator 210 and the condenser 220, air introduced through the intake port 121 may be resupplied into an indoor space with its temperature increased after moisture of the air has been removed.

That is, air drawn in through the intake port 121 may undergo heat exchange while passing through the low-temperature evaporator 210, and moisture may be separated from the air through heat exchange with this low temperature. The air passing through the evaporator 210 may undergo heat exchange while passing through the high-temperature condenser 220, and may be heated to an appropriate temperature through heat exchange with this high temperature and discharged indoors. Therefore, dry air of high temperature may be provided indoors.

Moisture separated from air while passing through the evaporator 210 may flow down along the surface of the evaporator 210, may be collected in the partition frame 500 located below the evaporator 210, may pass through the drain hole, and may be provided to the water tank 400 located below the partition frame.

Meanwhile, the dehumidifying part 200 may include the compressor 230 and an expander 240, forming a refrigeration cycle together with the heat exchanger 210 and 220 described above.

The compressor 230 may be provided in the third space of the lower space within the casing 100. By placing the compressor 230, which is relatively heavier than other components, in the center of the lower portion, the casing 100 may be prevented from tipping over.

Next, the dehumidifier according to the embodiment of the present disclosure may include the fan assembly 300.

The fan assembly 300 may be defined as an assembly having a blower fan 310 to generate airflow.

The fan assembly 300 may be provided in the upper space within the casing 100.

Specifically, as illustrated in FIGS. 2 and 6, the fan assembly 300 may be located on the air outlet side of the heat exchanger 210 and 220 (in particular, the condenser). Accordingly, air that passes through the intake port 121 and sequentially passes through the evaporator 210 and the condenser 220 may be introduced into the fan assembly 300.

As illustrated in FIGS. 2 and 5, the fan assembly 300 may include the blower fan 310 and a fan housing 320.

The fan housing 320 may be formed to be round relative to the center of rotation of the blower fan 310, and may have a discharge duct 323, which extends upward and guides the discharge flow of air, formed on one circumferential portion thereof. The end portion of the discharge duct 323 may be open and provided as an air outlet

As shown in FIG. 6, the air outlet of the discharge duct 323 may be formed to be aligned with the discharge port 141 of the upper cover 140 constituting the casing 100. That is, the discharge duct 323 may extend upward from the upper portion of the peripheral wall of the fan housing 320 and be aligned with the discharge port 141. Accordingly, air flowing along the discharge duct 323 may sequentially pass through the air outlet and the discharge port 141 of the upper cover 140 and then be discharged indoors.

As shown in FIG. 4, the fan housing 320 may have a fan motor 324 installed on the outer surface thereof, and the blower fan 310 may be positioned within the fan housing 320 and may be axially coupled to the fan motor 324. The fan motor 324 may be installed on the outer surface of the fan housing 320.

The blower fan 310 may be formed as a centrifugal fan (e.g., a Sirocco fan) having one surface (a surface facing the heat exchanger) open and multiple vanes formed along the periphery thereof. Accordingly, by the rotation of the blower fan 310, air may be drawn in through the air inlet of the fan housing 320. The drawn-in air may flow into the blower fan 310, be discharged in a radial direction, flow along the peripheral wall of the fan housing 320, and be discharged through the discharge duct 323 to the discharge port 141.

Next, the dehumidifier according to the embodiment of the present disclosure may include the electric part 600.

The electric part 600 may be a part or device made up of multiple circuit components for controlling the operation of each device.

The electric part 600 may be located in the lower space within the casing 100. Specifically, the electric part 600 may be located in the first space 101 within the casing 100. The electric part 600 may be fixed to the wall surface of the first vertical partition wall 510 within the first space 101.

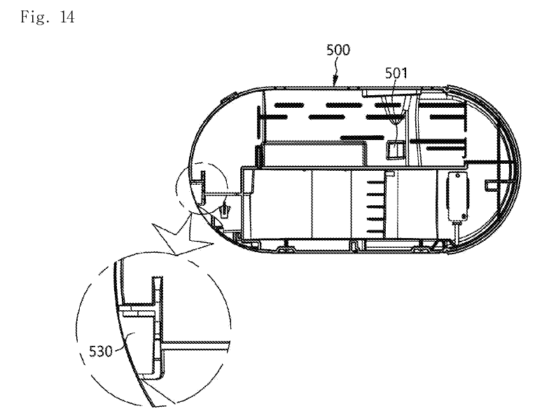

As illustrated in FIGS. 3 and FIG. 15, the electric part 600 may be composed of a main PCB 610 having multiple circuit components 601 and a cabinet 620 for protecting the main PCB 610 from the external environment.

The cabinet 620 may be formed of a metal material or a flame-retardant material to prevent the risk of fire due to heat generation or ignition of the circuit components 601.

The cabinet 620 may include two covers 621 and 622 that are separable from each other. That is, the cabinet 620 may include a first cover 621 constituting a rear surface thereof (a wall surface adjacent to the first vertical partition wall) and a second cover 622 constituting a front surface thereof (a wall surface adjacent to the casing). Accordingly, if necessary, the two covers 621 and 622 may be separated from each other to enable maintenance of the main PCB 610 located inside the cabinet 620.

Next, the dehumidifier according to the embodiment of the present disclosure may include the heat dissipation guide part 700.

The heat dissipation guide part 700 may be defined as a portion or component that guides airflow to dissipate heat from the electric part 600.

The heat dissipation guide part 700 may be configured to dissipate heat from the electric part 600 by utilizing airflow generated within the casing 100 by the operation of the fan assembly 300 without generating airflow forcibly. That is, the heat dissipation guide part 700 may allow indoor air, which is drawn in by air suction force generated by the operation of the fan assembly 300, to pass through the electric part 600, thereby allowing the electric part 600 to naturally dissipate heat.

The heat dissipation guide part 700 may be formed so that indoor air is introduced into the first space 101 in which the electric part 600 is located. To this end, the heat dissipation guide part 700 may be formed in any one of the portions forming the first space 101 (the partition frame, the first vertical partition wall, the peripheral casing, and the base frame).

In the embodiment of the present disclosure, it is proposed that the heat dissipation guide part 700 is formed on the portion of the base frame 130 at which the first space 101 is located. That is, considering that air suction force into the first space 101 is generated through the guide 530 of the partition frame 500 constituting the upper surface of the first space 101, indoor air may be introduced from the lower surface of the first space 101 to ensure that the air passes sufficiently through the interior of the first space 101 as much as possible.

In particular, as illustrated in FIG. 5, the heat dissipation guide part 700 may be provided on a portion of the base frame 130 facing the lower surface of the electric part 600. With this structure, air flowing into the first space 101 from the indoor space may hit the lower surface of the electric part 600 and then flow along the surface of the electric part 600, thereby being able to flow upward within the first space 101. That is, due to the position at which the heat dissipation guide part 700 is provided, air flowing into the first space 101 may sufficiently dissipate heat from the surface of the electric part 600.

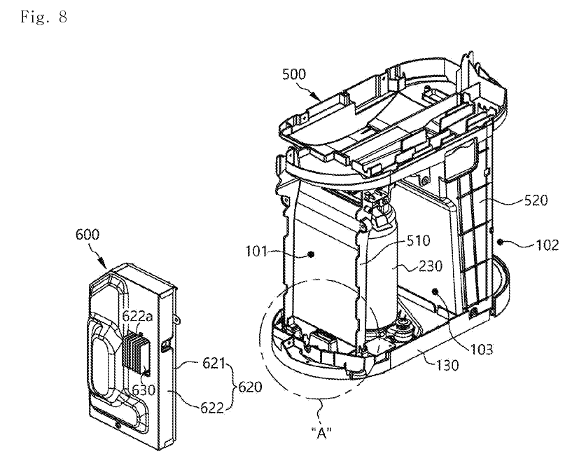

As illustrated in FIGS. 5 and 9, the heat dissipation guide part 700 may be formed as a tubular body having an opening of a predetermined size.

Although not shown, the heat dissipation guide part 700 may also be formed as a simple opening. However, in this case, moisture present on the upper surface of the base frame 130 may pass through the heat dissipation guide part 700 and be discharged indoors, which may cause the complaint of a user.

Taking this into consideration, the heat dissipation guide part 700 may be formed as a tubular body that protrudes upward from the base frame 130 and has an open interior. That is, the heat dissipation guide part 700 may protrude from the upper surface of the base frame 130, and accordingly, even if condensate accumulates on the upper surface of the base frame 130, the leakage of the condensate to the indoor floor through the heat dissipation guide part 700 may be prevented.

Moreover, since the heat dissipation guide part 700 is formed as the tubular body, indoor air may be discharged in a direction to which the heat dissipation guide part 700 is directed while the indoor air has directionality while passing through the heat dissipation guide part 700.

The opening of the heat dissipation guide part 700 may be formed to be open toward a portion of the lower surface of the electric part 600. Accordingly, indoor air introduced through the heat dissipation guide part 700 may be directly supplied to the electric part 600.

The opening of the heat dissipation guide part 700 may be formed as an elongated hole. That is, the heat dissipation guide part 700 may be formed as an elongated hole structure along the longitudinal direction of the lower surface of the electric part 600. For example, the heat dissipation guide part 700 may be formed to have an elongated opening along the longitudinal direction of the lower surface of the electric part 600, with the elongated opening being longer than the width of the lower surface of the electric part 600 and shorter than the length of the lower surface of the electric part 600. Accordingly, while ensuring sufficient airflow velocity, indoor air may be discharged toward the widest possible area of the lower surface of the electric part 600, thereby discharging heat from the electric part 600.

Meanwhile, it is preferable that the heat dissipation guide part 700 be positioned to be misaligned with the guide 530, rather than vertically facing the guide 530. That is, in order to allow indoor air flowing into the first space 101 through the heat dissipation guide part 700 to pass through as much of the first space 101 as possible, it is most preferable that the heat dissipation guide part 700 and the guide 530 do not face each other.

Accordingly, it is preferable that the guide 530 is formed to be positioned on a first side upper portion with respect to the electric part 600, and the heat dissipation guide part 700 is formed to be positioned on a second side lower portion with respect to the electric part 600. Of course, in the case of the heat dissipation guide part 700, considering the structure of the base frame 130, it may be formed to be positioned at the lower center portion of the electric part 600 as illustrated in the embodiment.

Below, a heat dissipation process for the above-described electric part 600 of the dehumidifier according to the embodiment of the present disclosure is described in detail.

First, the fan assembly 300 does not operate when the dehumidifier is not operating. Accordingly, no air suction force is provided to the upper space (the upper space of the partition frame) and the lower space (the lower space of the partition frame, the first space, the second space, and the third space) within the casing 100, so indoor air is not drawn in. Of course, since the dehumidifier is not operating, no heat is generated in the electric part 600.

When the dehumidifier is operated in the initial state described above, the compressor 230 of the dehumidifying part 200 may be operated.

By the operation of the compressor 230, refrigerant in the refrigeration cycle is repeatedly compressed, condensed, expanded, and evaporated sequentially. Accordingly, a cold refrigerant may pass through the evaporator 210 constituting the dehumidifying part 200, and a hot refrigerant may pass through the condenser 220, thereby exchanging heat with air passing through the evaporator 210 and the condenser 220.

When the compressor 230 operates, the fan assembly 300 may also operate.

By the operation of the fan assembly 300, a low pressure may be generated between the opening (bellmouth) of the fan housing 320 and the heat exchanger 210 and 220, which causes air suction force, and indoor air may be drawn in through the intake port 121 of the second peripheral casing 120 by the air suction force.

After that, while the indoor air drawn in passes through the evaporator 210 of the heat exchanger 210 and 220, moisture may be separated from the air, and the temperature of the air may increase while the air passes through the condenser 220.

Subsequently, the air that has passed through the heat exchanger 210 and 220 may flow into the fan housing 320 through the opening thereof, flow along the discharge duct 323 of the fan housing 320, and may be supplied to the indoor space through the discharge port of the upper cover 140.

Therefore, dehumidification of indoor air may be achieved by repeating the above-described process.

Meanwhile, during the dehumidification operation of the indoor air of the dehumidifier as described above, the first space 101 of the lower space within the casing 100 may receive air suction force generated in the upper space within the casing 100, in which the heat exchanger 210 and 220 is located, through the opening of the guide 530.

That is, a portion of the air suction force generated by the operation of the fan assembly 300 may be provided to the first space 101 through the guide 530, thereby generating an airflow in which air within the first space 101 flows to the fan assembly 300 through the guide 530.

In this case, a negative pressure may be generated inside the first space 101 to discharge air through the guide 530, and indoor air may be drawn in through the heat dissipation guide part 700 formed in the base frame 130 of the first space 101 by the negative pressure.

Indoor air drawn into the first space 101 may be guided by the heat dissipation guide part 700 while passing through the heat dissipation guide part 700 and may be discharged toward the lower surface of the electric part 600.

Subsequently, the air may flow along the surface of the second cover 622 constituting the electric part 600 while being moved upward by the air suction force provided at the upper corner portion of the first space 101.

Accordingly, the heat of the electric part 600 may be dissipated by the air flowing along the surface of the second cover 622, thereby preventing excessive temperature rise of the circuit components 601 within the cabinet 620.

Air whose heat has been dissipated while the air is passing through the electric part 600 may flow to the guide 530, pass through the guide 530, and may be provided to the upper space within the casing 100. Accordingly, the air dissipating heat from the electric part 600 may be supplied to the fan assembly 300 located in the upper space within the casing 100 and then discharged indoors through the discharge port 141 of the upper cover 140.

In this way, in the dehumidifier of the present disclosure, the heat dissipation guide part 700 may be formed on the base frame 130 to dissipate heat from the electric part 600 even if a separate heat-dissipating fan is not provided for heat dissipation.

In the dehumidifier of the present disclosure, a separate heat-dissipating fan may not be provided, thereby minimizing the volume of the electric part 600.

In the dehumidifier of the present disclosure, the opening through which air is drawn into the first space 101 in which the electric part 600 is located and the opening through which air is discharged may be positioned as far apart from each other as possible, and the electric part 600 may be positioned therebetween, thereby improving the performance of dissipating heat of the electric part 600.

When the heat dissipation guide part 700 is provided, there may be a temperature reduction effect of approximately 20 to 30%.

Meanwhile, the dehumidifier of the present disclosure may be implemented in various forms other than the above-described embodiment. Each embodiment is described as follows.

As an example according to another aspect of the present disclosure, as illustrated in FIGS. 2, 3, 7, and 8, the electric part 600 may be provided with a heat dissipation fin 630 for dissipating heat from the main PCB 610 provided within the cabinet 620, wherein the heat dissipation fin 630 may be formed to be exposed to the outside of the second cover 622 of the cabinet 620. In this case, the heat dissipation fin 630 may be formed by spacing a plurality of thin plates apart from each other.

That is, an exposure hole 622a may be formed in the second cover 622 of the cabinet 620, and the heat dissipation fin 630 may be exposed to the outside of the second cover 622 through the exposure hole 622a. Accordingly, air flowing along the surface of the cabinet 620 may exchange heat with the heat dissipation fin 630, thereby preventing excessive temperature rise of the various circuit components 601 of the main PCB 610.

Meanwhile, the heat dissipation fin 630 provided in the electric part 600 may be formed in a shape for improving heat exchange performance.

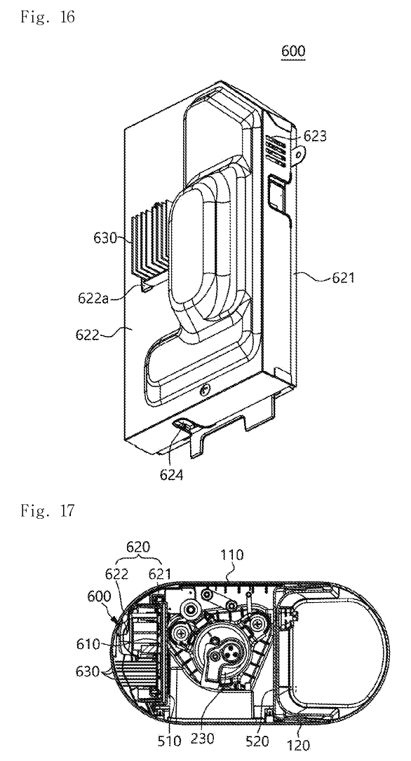

For example, as illustrated in FIG. 17, each of the thin plates of the heat dissipation fin 630 may be formed to have a different length along the inclination or curvature of the inner surface of the casing 100 adjacent to the thin plate.

Accordingly, the heat exchange area of the heat dissipation fin 630 may be maximized, thereby improving heat dissipation performance.

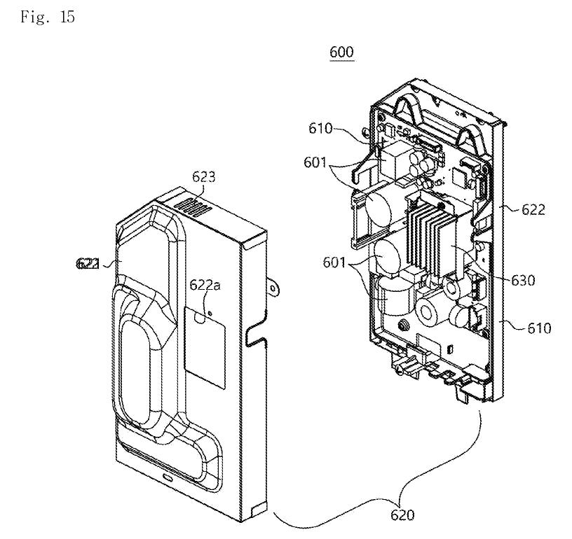

As another example according to a different aspect of the present disclosure, as illustrated in FIGS. 15 and 16, the cabinet 620 constituting the electric part 600 may include a first opening 623. That is, by forming the first opening in the cabinet, high temperature heat generated from the circuit components 601 may be forcibly discharged through the first opening 623 by the air suction force of the fan assembly 300.

The first opening 623 may be formed on the upper surface of the cabinet 620. Of course, the first opening 623 may be formed on the side surface of the cabinet 620.

The cabinet 620 may include a second opening 624, which is open to allow air within the first space 101 to flow into the cabinet 620.

The second opening 624 may be formed on the bottom surface of the cabinet 620. Accordingly, some of air that passes through the heat dissipation guide part 700 and is discharged to the lower surface of the cabinet 620 may flow into the cabinet 620 through the second opening 624, thereby directly dissipating heat from the various circuit components 601 of the main PCB 610.

As another example according to a different aspect of the present disclosure, although not shown, the partition frame 500 may further include an opening to transfer air suction force generated in the upper space of the casing 100 to the first space 101, in addition to the guide 530.

Accordingly, the dehumidifier of the present disclosure may be implemented in various forms.

In the above, all the components according to the embodiments of the present disclosure are described as being coupled to each other as one or being operated in the coupled state, but the present disclosure is not necessarily limited to the embodiments. That is, if it is within the scope of the present disclosure, at least one of all of the components may be selectively combined and operated. In addition, the terms such as "include", "compose", or "have" as described above means that the corresponding components can be inherent unless specifically stated to the contrary. Accordingly, it should be interpreted that other components are not excluded, but may further be included. All terms, including technical or scientific terms, have the same meaning as generally understood by those skilled in the art to which the present disclosure belongs, unless otherwise defined. Commonly used terms, such as terms defined in a dictionary, should be interpreted as being consistent with the contextual meaning of the related art, and are not to be interpreted as ideal or excessively formal meanings unless explicitly defined in the present disclosure.

The above explanation is merely an exemplary description of the technical idea of the present disclosure, and those skilled in the art to which the present disclosure belongs may make various modifications and variations without departing from the essential characteristics of the present disclosure. Accordingly, the embodiments disclosed in the present disclosure are intended to explain rather than limit the technical idea of the present disclosure, and the scope of the technical idea of the present disclosure is not limited by these embodiments. The scope of protection of the present disclosure should be interpreted by the claims below, and all technical ideas within the equivalent scope should be interpreted as being included in the scope of the claims of the present disclosure.

What is claimed is:

1. A dehumidifier comprising:
a casing configured to provide an installation space;
a base frame constituting a bottom portion of the casing;
a partition frame configured to divide the installation space within the casing into an upper space and a lower space;
a dehumidifying part provided within the casing and configured to separate moisture from air;
a fan assembly provided within the casing and configured to generate airflow; and
an electric part provided within the casing and having multiple circuit components for controlling an operation of each device,
wherein the base frame comprises a heat dissipation guide part that guides air to be drawn in from outside the casing and discharged to the electric part when the fan assembly is operating.

2. The dehumidifier of claim 1, wherein vertical partition walls are formed on a lower surface of the partition frame so as to divide the lower space within the casing into a plurality of spaces, and
the electric part is located within one space of the plurality of spaces.

3. The dehumidifier of claim 2, wherein the heat dissipation guide part is formed to allow air to flow into the space in which the electric part is located.

4. The dehumidifier of claim 1, wherein the heat dissipation guide part is formed as a tubular body that protrudes upward from the base frame and has an open interior.

5. The dehumidifier of claim 1, wherein the heat dissipation guide part is formed to be open toward a portion of a lower surface of the electric part.

6. The dehumidifier of claim 5, wherein the heat dissipation guide part is formed to have an elongated opening along a longitudinal direction of the lower surface of the electric part, with the elongated opening being shorter than a length of the lower surface of the electric part and longer than a width of the lower surface.

7. The dehumidifier of claim 6, wherein a first opening for allowing air to flow into the electric part is formed on the lower surface of the electric part.

8. The dehumidifier of claim 7, wherein the first opening is positioned so as to be vertically misaligned with at least a portion of the opening of the heat dissipation guide part.

9. The dehumidifier of claim 6, wherein a second opening for discharging air to the outside is formed on an upper surface of the electric part.

10. The dehumidifier of claim 9, wherein the partition frame has a passage hole through which air flowing out through the second opening flows into the upper space within the casing.

11. The dehumidifier of claim 10, wherein the passage hole is positioned to be vertically misaligned with the second opening.

12. The dehumidifier of claim 1, wherein an exposure hole is formed on an outer surface of the electric part, and
a heat dissipation fin is installed to be exposed through the exposure hole to dissipate heat from the circuit components inside the electric part.

13. The dehumidifier of claim 12, wherein the heat dissipation fin is formed by installing a plurality of thin plates spaced apart from each other.

14. The dehumidifier of claim 13, wherein each of the thin plates is formed to have a different length along inclination or curvature of an inner surface of the casing adjacent to the thin plate.

15. The dehumidifier of claim 1, wherein a guide through which air passing through the electric part passes is formed on the partition frame.

16. The dehumidifier of claim 15, wherein the guide and an opening of the heat dissipation guide part are positioned to be misaligned vertically.

17. The dehumidifier of claim 15, wherein the partition frame is formed to be inclined upward gradually toward a peripheral portion thereof.

18. The dehumidifier of claim 17, wherein the guide is formed on one periphery of the partition frame to allow the upper space and the lower space to communicate with each other.

19. The dehumidifier of claim 15, wherein an upper end of the guide is formed to protrude upward from an upper surface of the partition frame.

20. The dehumidifier of claim 15, wherein the partition frame is formed to be inclined upward gradually toward a portion on which the guide is formed.
